(19) United States
(12) Patent Application Publication
(10) Pub. No.: US 2026/0173954 A1
(43) Pub. Date: Jun. 18, 2026

(54) PACKAGE STRUCTURE AND METHOD FOR FORMING THE SAME

(71) Applicant: STATS ChipPAC Semiconductor (Jiangyin) Co., LTD., Jiangyin (CN)

(72) Inventors: Chuanming TANG, Jiangyin (CN); Jian XU, Jiangyin (CN); Jeonghan KIM, Jiangyin (CN)

(21) Appl. No.: 19/393,364

(22) Filed: Nov. 18, 2025

(30) Foreign Application Priority Data
Dec. 13, 2024 (CN) 202411846870.0

(51) Int. Cl. H10W 74/47; H10W 72/00; H10W 72/30; H10W 74/15; H10W 90/00

(52) U.S. Cl. CPC H10W 74/47; H10W 72/072; H10W 72/073; H10W 72/07302; H10W 72/354; H10W 72/383; H10W 72/387; H10W 74/15; H10W 90/724; H10W 90/734

(57) ABSTRACT

A package structure and a method for forming the package structure are provided. The package structure includes: a substrate, where the substrate includes an optical module area, the optical module area includes an electrical connection area and an edge area adjacent thereto arranged in a direction toward an edge of the substrate; an optical device arranged on a top of the substrate in the optical module area, where the electrical connection area of the substrate is electrically connected to the optical device; a barrier structure located at the top of the substrate in the edge area, where a surface of the barrier structure is provided with a non-wetting material; and an underfill layer located between the optical device and the substrate in the electrical connection area, where the underfill layer is in contact with the substrate and the optical device.

### CROSS-REFERENCE TO RELATED APPLICATIONS

This application claims the benefit of priority to Chinese Application No. 202411846870.0, filed December 13, 2024, which is incorporated herein by reference in its entirety.

### TECHNICAL FIELD

The present disclosure relates to the field of semiconductor package, and particularly relates to a package structure and a method for forming the same.

### BACKGROUND

With the rapid development of data centers and artificial intelligence applications, market demand for high-speed, high-bandwidth, low-power optical communication solutions continues to grow. Co-Packaged Optics (CPO) technology, with its exceptional integration and transmission efficiency, has become the preferred solution to meet this market demand.

The co-packaged optics technology is an advanced optical package technology, the co-packaged optics technology integrates optical devices and chips on a substrate, which significantly shortens the electrical signal transmission path, thereby improving signal transmission speed and integrity, thus reducing size, improving efficiency, and reducing power consumption.

### SUMMARY

The embodiment of the present disclosure provides a package structure, which includes: a substrate, the substrate including an optical module area, the optical module area including an electrical connection area arranged along a direction close to an edge of the substrate and an edge area adjacent to it; an optical device arranged at the top of the substrate of the optical module area, and the electrical connection area of the substrate is electrically connected with the optical device; a barrier structure located at the top of the substrate of the edge area, and the surface of the barrier structure has a non-wetting material; and an underfill layer located between the optical device and the substrate of the electrical connection area, and the underfill layer is in contact with the substrate and the optical device.

In some implementations, the barrier structure includes a one-piece structural layer; or the barrier structure includes a base material layer and a barrier layer covering the surface of the base material layer.

In some implementations, the material of the one-piece structural layer includes a non-wetting material; or the material of the barrier layer includes a non-wetting material.

In some implementations, the non-wetting material includes one or two of silicon oxide and silicon nitride.

In some implementations, the direction close to the edge of the substrate is defined as the first direction, the barrier structure extends along a second direction and is arranged in parallel and spaced apart along the first direction, the first direction and the second direction being perpendicular to each other.

In some implementations, the number of the barrier structures is between 1 and 4.

In some implementations, the direction close to the edge of the substrate is defined as the first direction, the distance of the barrier structure in the first direction is 10 micrometers to 20 micrometers.

In some implementations, in the normal direction of the substrate, the optical device and the substrate have between them a first spacing, the height of the optical device is between 5% and 25% of the first spacing.

In some implementations, the package structure further includes: a first conductive bump located on the surface of the optical device facing the substrate, and the top surface of the first conductive bump is electrically connected with the optical device, and the bottom surface of the first conductive bump is electrically connected with the electrical connection area of the substrate; the underfill layer covers the sidewalls of the first conductive bump; and the direction close to the edge of the substrate is defined as the first direction, the distance of the barrier structure and the nearest first conductive bump in the first direction is between 100 micrometers and 300 micrometers.

In some implementations, the optical device spans the edge area of the substrate and protrudes from the substrate.

In some implementations, the barrier structure is also located on the surface of the optical device facing the edge area.

In some implementations, along the direction close to the edge of the substrate, the barrier structures on the edge area and the barrier structures on the optical device are arranged in a staggered manner; or, along the direction close to the edge of the substrate, the barrier structures on the edge area and the barrier structures on the optical device are arranged in a crossed manner.

In some implementations, the material of the underfill layer includes epoxy resin.

Correspondingly, the embodiment of the present disclosure also provides a method for forming a package structure, which includes: providing a substrate, the substrate includes an optical module area, the optical module area including an electrical connection area arranged along a direction close to an edge of the substrate and an edge area adjacent to it; arranging an optical device at the top of the substrate of the optical module area, and the electrical connection area of the substrate is electrically connected with the optical device; forming a barrier structure at the top of the substrate of the edge area, and the surface of the barrier structure has a non-wetting material; and after forming the optical device and the barrier structure, forming an underfill layer between the optical device and the substrate of the electrical connection area, and the underfill layer is in contact with the substrate and the optical device.

In some implementations, the barrier structure includes a one-piece structural layer; or the barrier structure includes a base material layer and a barrier layer covering the surface of the base material layer.

In some implementations, the material of the one-piece structural layer includes non-wetting material; or the material of the barrier layer includes non-wetting material.

In some implementations, the process for forming the barrier structure at the top of the substrate of the edge area includes a spraying process, a printing process, or a sputtering process.

In some implementations, the step of arranging an optical device at the top of the substrate of the optical module area includes: providing an optical device, a first conductive bump being formed on the surface of the optical device facing the substrate, and the top of the first conductive bump is electrically connected with the optical device; soldering the first conductive bump to the electrical connection area of the substrate through a high-temperature reflow process, and the bottom surface of the first conductive bump is electrically connected with the electrical connection area of the substrate; and in the step of forming the underfill layer, the underfill layer covering the sidewalls of the first conductive bump.

In some implementations, after arranging the optical device, a barrier structure is formed at the top of the substrate of the edge area; in the step of forming the barrier structure, it further includes: forming the barrier structure on the surface of the optical device facing the edge area.

In some implementations, along the direction close to the edge of the substrate, in the step of forming the barrier structure, the barrier structures on the edge area and the barrier structures on the optical device are arranged in a staggered manner; or, along the direction close to the edge of the substrate, in the step of forming the barrier structure, the barrier structures on the edge area and the barrier structures on the optical device are arranged in a crossed manner.

In some implementations, the direction close to the edge of the substrate is defined as the first direction, the barrier structure extends along a second direction and is arranged in parallel and spaced apart along the first direction, the first direction and the second direction being perpendicular to each other.

### BRIEF DESCRIPTION OF THE DRAWINGS

FIGS. 1 to 3 illustrate structural schematic diagrams corresponding to a package structure;

FIGS. 4 to 7 are structural schematic diagrams corresponding to the first embodiment of the package structure of the present disclosure;

FIGS. 8 to 9 illustrate structural schematic diagrams corresponding to the second embodiment of the package structure of the present disclosure;

FIGS. 10 to 17 are structural schematic diagrams corresponding to each step of the first embodiment of the formation method of the package structure of the present disclosure; and

FIGS. 18 to 19 illustrate structural schematic diagrams corresponding to each step of the second embodiment of the formation method of the package structure of the present disclosure.

### DETAILED DESCRIPTION

Currently, the reliability and product yield of the package structure formed by co-packaged optics technology still needs to be improved. . Now, in conjunction with a package structure, the reasons why its reliability and product yield still need to be improved are analyzed.

Compared to the related art, the technical solutions of the embodiment of the present disclosure have the following advantages:

In the package structure provided by the embodiments of the present disclosure, the optical device is arranged at the top of the substrate of the optical module area, and the electrical connection area of the substrate is electrically connected with the optical device, and the barrier structure is located at the top of the substrate of the edge area, and the surface of the barrier structure has a non-wetting material; since the surface of the barrier structure has a non-wetting material, the non-wetting material has the function of blocking the overflow of liquid material, and during the process of arranging an underfill layer between the optical device and the substrate of the electrical connection area, the barrier structure can block the underfill layer from overflowing toward the direction close to the edge area, the probability of the underfill layer overflowing the periphery of the substrate is reduced, so that the reliability of the package structure and product yield are improved.

In the method for forming the package structure provided by the embodiment of the present disclosure, the optical device is arranged at the top of the substrate of the optical module area, and the electrical connection area of the substrate is electrically connected with the optical device, the barrier structure is formed at the top of the substrate of the edge area, and the surface of the barrier structure has a non-wetting material; since the surface of the barrier structure has a non-wetting material, the non-wetting material has the function of blocking the overflow of liquid material, and during the subsequent process of arranging an underfill layer between the optical device and the substrate of the electrical connection area, the barrier structure can block the underfill layer from overflowing toward the direction close to the edge area, the probability of the underfill layer overflowing the periphery of the substrate is reduced, so that the reliability of the package structure and product yield are improved.

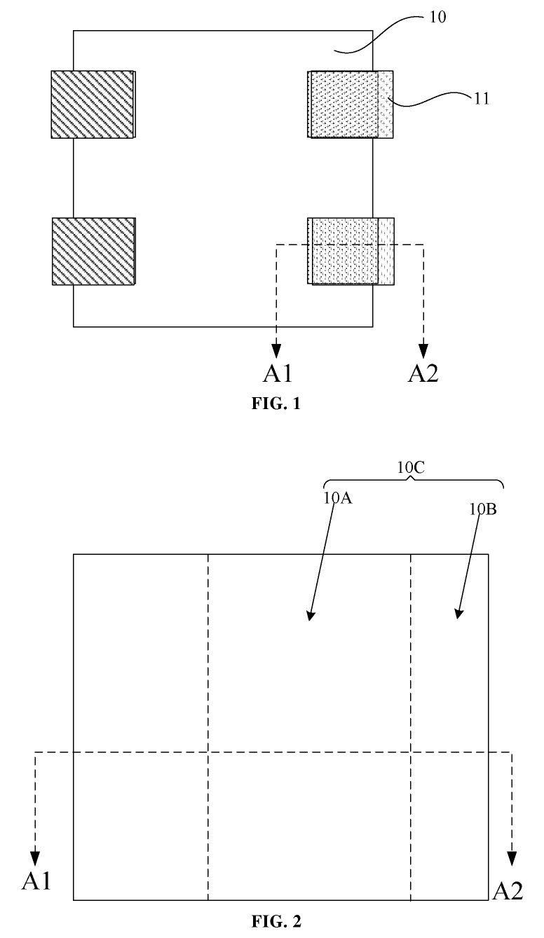

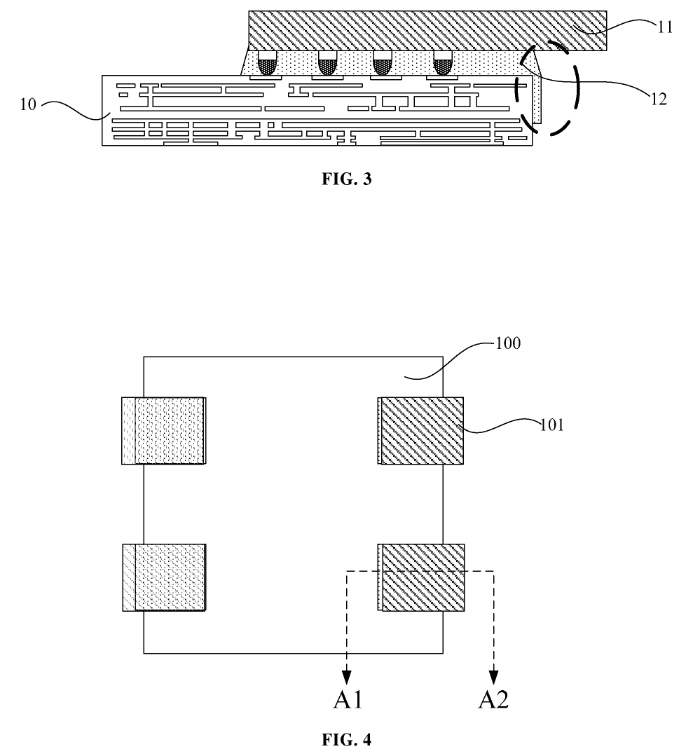

FIGS. 1 to 3 illustrate structural schematic diagrams corresponding to a package structure. Wherein FIG. 1 is a top view schematic diagram of the package structure, FIG. 2 is a top view schematic diagram of the optical module area, and FIG. 3 is a cross-sectional schematic diagram of FIG. 2 and FIG. 1 along the A1A2 direction.

Referring to FIGS. 1 to 3, the package structure includes: a substrate 10, the substrate 10 including an optical module area 10C, the optical module area 10C including an electrical connection area 10A arranged along a direction close to an edge of the substrate 10 and an edge area 10B adjacent to it; an optical device 11 arranged at the top of the substrate 10 of the optical module area 10C, and the electrical connection area 10A of the substrate 10 is electrically connected with the optical device 11; and an underfill layer 12 located between the optical device 11 and the substrate10 of the electrical connection area 10A, and the underfill layer 12 is in contact with the substrate 10 and the optical device 11.

During the process of arranging the underfill layer 12 between the optical device 11 and the substrate 10 of the electrical connection area 10A, it is unable to control the underfill layer 12 close to the edge area 10B of the substrate 10, which increases the probability of the underfill layer 12 overflowing to the periphery of the substrate 10 (as indicated by the dashed circle in FIG. 3), so that the reliability and product yield of the package structure is affected.

In order to solve the above technical problem, the embodiments of the present disclosure provide a package structure, which includes: a substrate, the substrate including an optical module area, the optical module area including an electrical connection area arranged along a direction close to an edge of the substrate and an edge area adjacent to it; an optical device arranged at the top of the substrate of the optical module area, and the electrical connection area of the substrate is electrically connected with the optical device; a barrier structure located at the top of the substrate of the edge area, and the surface of the barrier structure has a non-wetting material; and an underfill layer located between the optical device and the substrate of the electrical connection area, and the underfill layer is in contact with the substrate and the optical device.

In the package structure provided by the embodiments of the present disclosure, the optical device is arranged at the top of the substrate of the optical module area, and the electrical connection area of the substrate is electrically connected with the optical device, and the barrier structure is located at the top of the substrate of the edge area, and the surface of the barrier structure has a non-wetting material; since the surface of the barrier structure has a non-wetting material, the non-wetting material has the function of blocking the overflow of liquid material, and during the process of arranging an underfill layer between the optical device and the substrate of the electrical connection area, the barrier structure can block the underfill layer from overflowing toward the direction close to the edge area, the probability of the underfill layer overflowing the periphery of the substrate is reduced, so that the reliability of the package structure and product yield are improved.

In order to make the above objects, features, and advantages of the embodiments of the present disclosure more obvious and understandable, the specific embodiments of the present disclosure are described in detail below in conjunction with the accompanying drawings.

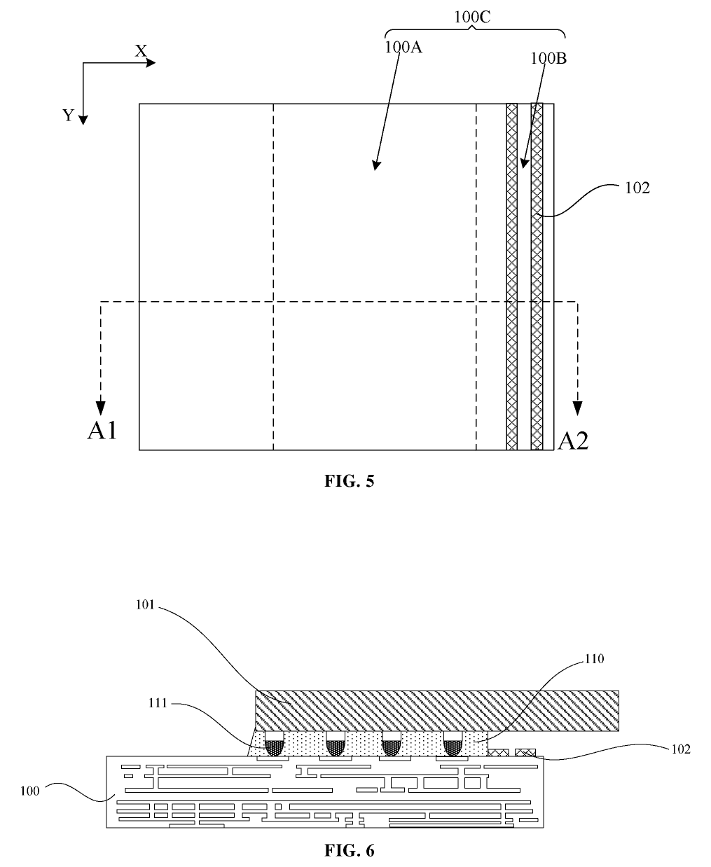

FIGS. 4 to 7 are structural schematic diagrams corresponding to the first embodiment of the package structure of the present disclosure. Wherein FIG. 4 is a top view schematic diagram of the package structure, FIG. 5 is a top view schematic diagram of the optical module area, and FIG. 6 is a cross-sectional schematic diagram of FIG. 5 along the A1A2 direction.

The package structure includes: a substrate 100, the substrate 100 including an optical module area 100C, the optical module area 100C including an electrical connection area 100A arranged along a direction close to an edge of the substrate 100 and an edge area 100B adjacent to it; an optical device 101 arranged at the top of the substrate 100 of the optical module area 100C, and the electrical connection area 100A of the substrate 100 is electrically connected with the optical device 101; a barrier structure 102 located at the top of the substrate 100 of the edge area 100B, and the surface of the barrier structure 102 has a non-wetting material; and an underfill layer 110 located between the optical device 101 and the substrate 100 of the electrical connection area 100A, and the underfill layer 110 is in contact with the substrate 100 and the optical device 101.

It should be noted that the optical device 101 is arranged at the top of the substrate 100 of the optical module area 100C, and the electrical connection area 100A of the substrate 100 is electrically connected with the optical device 101, and the barrier structure 102 is located at the top of the substrate 100 of the edge area 100B, and the surface of the barrier structure 102 has a non-wetting material; since the surface of the barrier structure 102 has a non-wetting material, the non-wetting material has the function of blocking the overflow of liquid material, and during the process of arranging an underfill layer 110 between the optical device 101 and the substrate 100 of the electrical connection area 100A, the barrier structure 102 can block the underfill layer 110 from overflowing toward the direction close to the edge area 100B, the probability of the underfill layer 110 overflowing the periphery of the substrate 100 is reduced, so that the reliability of the package structure and product yield are improved.

In some implementations, the substrate 100 provides a process platform for arranging the optical device 101 to support the optical device 101, meanwhile, the substrate 100 has conductive lines in it, the conductive lines are used to supply power or transmit electrical signals for the optical device 101, thereby achieving the package and circuit integration of the optical device 101.

In the present embodiment, the substrate 100 may be one of silicon substrate, Redistribution Layer (RDL) substrate, resin substrate, Printed Circuit Board (PCB), ceramic substrate, glass substrate, or Flexible Printed Circuit (FPC). In one embodiment, the substrate 100 may be a single-layer board or a multi-layer board. In one embodiment, the substrate 100 may serve as an interposer board (or interposer).

In some implementations, the optical module area 100C is the area for subsequent arrangement of the optical devices 101, by arranging the optical devices 101 on the substrate 100, the distance between the optical devices 101 and other chips can be shortened, which improves the transmission speed of electrical signals and achieves lower signal latency and lower power consumption.

As an example, the optical module area 100C includes an electrical connection area 100A arranged along a direction close to an edge of the substrate 100 and an edge area 100B adjacent to it.

It should be noted that the electrical connection area 100A is the area where the optical device 101 is electrically connected with the substrate 100, in some implementations, it is the area where the conductive bumps in the optical device 101 are electrically connected with the substrate 100.

It should also be noted that the edge area 100B is the area where the barrier structure 102 is arranged, by arranging the barrier structure 102 at the edge area 100B, it can block the underfill layer 110 from overflowing toward the direction close to the edge area 100B, the probability of the underfill layer 110 overflowing the periphery of the substrate 100 is reduced, so that the reliability of the package structure and product yield are improved.

In some implementations, the optical device 101 is used to receive optical signals, by arranging the optical device 101 at the optical module area 100C of the substrate 100, a shorter optical path can be achieved, thereby improving the efficiency of optical communication.

As an example, in order to facilitate the reception of optical signals by the optical device 101, the optical device 101 spans the edge area 100B of the substrate 100 and protrudes from the substrate 100.

As an example, the optical device 101 includes one or two of an optoelectronic chip and an optical transceiver.

In other embodiments, the optical device 101 may also be replaced by other types of optical devices according to performance requirements.

In the present embodiment, the package structure further includes: a first conductive bump 111 located on the surface of the optical device 101 facing the substrate 100, and the top surface of the first conductive bump 111 is electrically connected with the optical device 101, and the bottom surface of the first conductive bump 111 is electrically connected with the electrical connection area 100A of the substrate 100.

It should be noted that the first conductive bump 111 serves to arrange the optical device 101 on the substrate 100, which reduces the risk of the optical device 101 and the substrate 100 separating from each other, meanwhile, the first conductive bump 111 also serves to achieve electrical connection between the optical device 101 and the substrate 100.

It should also be noted that during the formation of the package structure, the first conductive bump 111 is formed through an electroplating process, which can enable the first conductive bump 111 to be formed in a designated position of the electrical connection area 100A of the substrate 100, thereby facilitating the mounting of the first conductive bump 111 on the substrate 100, meanwhile, the first conductive bump 111 formed through an electroplating process has the characteristics of high connection reliability, and etc., which can reduce the risk of separation of the first conductive bump 111 from the substrate 100.

As an example, the material of the first conductive bump 111 includes one or more of gold, lead-tin, silver-tin, gold-tin, and copper-tin.

It should be noted that the barrier structure 102 is located at the top of the substrate 100 of the edge area 100B, and the surface of the barrier structure 102 has a non-wetting material, since the surface of the barrier structure 102 has a non-wetting material, the non-wetting material has the function of blocking the overflow of liquid material, and during the process of arranging an underfill layer 110 between the optical device 101 and the substrate 100 of the electrical connection area 100A, the barrier structure 102 can block the underfill layer 110 from overflowing toward the direction close to the edge area 100B, the probability of the underfill layer 110 overflowing the periphery of the substrate 100 is reduced, so that the reliability of the package structure and product yield are improved.

In the present embodiment, the barrier structure 102 includes a one-piece structural layer.

In some implementations, the one-piece structural layer refers to the barrier structure 102 which is made of the same material.

In the present embodiment, the material of the one-piece structural layer includes a non-wetting material.

It should be noted that the barrier structure 102 is made of non-wetting material, the non-wetting material serves to block the overflow of liquid material, so that the barrier structure 102 can block the underfill layer 110 from overflowing towards the edge area 100B.

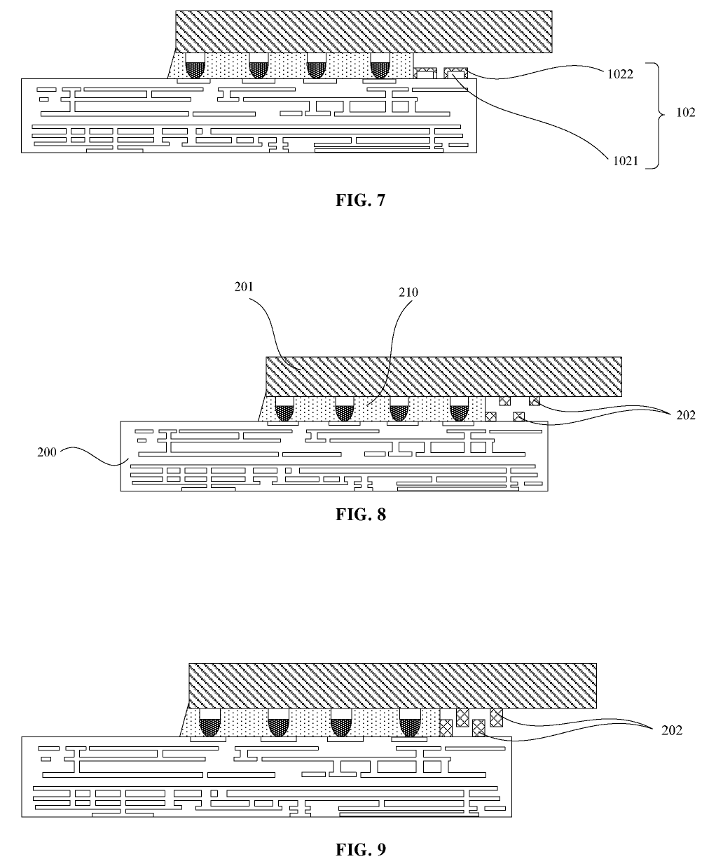

In other embodiments, as shown in FIG. 7, the barrier structure 102 may further include a base material layer 1021 and a barrier layer 1022 covering the surface of the base material layer 1021.

The barrier layer 1022 is formed on the surface of the base material layer 1021, and the surface of the barrier layer 1022 has a non-wetting material, which enables the barrier layer 1022 to block the underfill layer 110 from overflowing toward the direction of the edge area 100B, reducing the probability of the underfill layer 110 overflowing the periphery of the substrate 100.

The base material layer 1021 serves to support the barrier layer 1022, ensuring that the entire barrier structure 102 has a certain strength and height.

In some implementations, the material of the barrier layer 1022 includes a non-wetting material.

The material of the barrier layer 1022 is made of non-wetting material, the non-wetting material serves to block the overflow of liquid materials, correspondingly, during the process of arranging the underfill layer 110 between the optical device 101 and the substrate 100 of the electrical connection area 100A, the barrier layer 1022 can block the underfill layer 110 from overflowing toward the direction of the edge area 100B, reducing the probability of the underfill layer 110 overflowing the periphery of the substrate 100.

In the present embodiment, the non-wetting material includes one or two of silicon oxide and silicon nitride.

Silicon oxide and silicon nitride have high density and are non-conductive, and thus will not affect circuits in the optical devices. Meanwhile, silicon oxide and silicon nitride can block the underfill layer 110 from overflowing toward the direction of the edge area 100B, reducing the probability of the underfill layer 110 overflowing the periphery of the substrate 100.’

In the present embodiment, the direction close to the edge of the substrate 100 is defined as the first direction (as shown in the X-direction in FIG. 5), the barrier structure 102 extends along a second direction (as shown in the Y-direction in FIG. 5) and are arranged in parallel and spaced apart along the first direction, the first direction and the second direction being perpendicular to each other.

It should be noted that the barrier structures 102 are arranged in parallel and spaced apart along the first direction, during the process of arranging the underfill layer 110 between the optical device 101 and the substrate 100 of the electrical connection area 100A, even if the underfill layer 110 overflows the first barrier structure 102, subsequent barrier structures 102 in the first direction can still serve to block the overflow of the underfill layer 110, reducing the probability of the underfill layer 110 overflowing the periphery of the substrate 100.

It should also be noted that the barrier structure 102 extends along the second direction, that is to say, the boundary of the electrical connection area 100A close to the edge of the substrate 100 is enclosed by the barrier structure 102, so that the overflow of the underfill layer 110 of the entire electrical connection area 100A is blocked by the barrier structure 102, further reducing the probability of the underfill layer 110 overflowing the periphery of the substrate 100.

In some implementations, the number of barrier structures 102 should not be too high. If the number of barrier structures 102 is too high, the barrier structures 102 may occupy too large an area in the edge area 100B. Given a fixed area for the optical module area 100C, this reduces the area of the electrical connection area 100A. Consequently, the bonding area between the optical device 101 and the substrate 100 is decreased, which increases the risk of separation and also impairs the effectiveness of the electrical connection between them. For this reason, in the present embodiment, the number of barrier structures 102 is between 1 and 4.

It should be noted that the direction close to the edge of the substrate 100 is defined as the first direction, the distance of the barrier structure 102 in the first direction should be neither too small nor too large. If the distance of the barrier structure 102 in the first direction is too small, then it increases the process difficulty for forming the barrier structure 102 during the formation of the barrier structure 102, meanwhile, it also affects the effectiveness of the barrier structure 102 in blocking the overflow of liquid materials, increasing the probability of the underfill layer 110 overflowing the periphery of the substrate 100; if the distance of the barrier structure 102 in the first direction is too large, then it tends to cause the area of the edge area 100B occupied by the barrier structure 102 to be too large, in the case where the area of the optical module area 100C is fixed, the area of the electrical connection area 100A is reduced, thereby decreasing the joint area between optical device 101 and substrate 100, increasing the risk of separation between the optical device 101 and the substrate 100. For this reason, in the present embodiment, the direction close to the edge of the substrate 100 is defined as the first direction, and the distance of the barrier structure 102 in the first direction is between 10 micrometers and 20 micrometers.

In some implementations, in the normal direction of the substrate 100, there is a first spacing between the optical device 101 and the substrate 100, and the percentage of the height of the barrier structure 102 relative to the first spacing should be neither too large nor too small. If the percentage of the height of the barrier structure 102 relative to the first spacing is too small, then it affects the effectiveness of the barrier structure 102 in blocking the overflow of liquid materials, increasing the probability of the underfill layer 110 overflowing the periphery of the substrate 100; if the percentage of the height of the barrier structure 102 relative to the first spacing is too large, then the manufacturing difficulty and manufacturing cost of the barrier structure 102 is higher. For this reason, in the present embodiment, in the normal direction of the substrate 100, there is a first spacing between the optical device 101 and the substrate 100, and the height of the barrier structure 102 is between 5% and 25% of the first spacing.

It should be noted that the direction close to the edge of the substrate 100 is defined as the first direction, the distance of the barrier structure 102 and the nearest first conductive bump 111 in the first direction should be neither too small nor too large. If the distance of the barrier structure 102 and the nearest first conductive bump 111 in the first direction are too small, then it increases the difficulty of arranging the underfill layer 110 between the barrier structure 102 and the nearest first conductive bump 111, which prevents the underfill layer 110 from fully covering the sidewalls of the first conductive bump 111, thus increasing the risk of the sidewalls of the first conductive bump 111 of the nearest barrier structure 102 being exposed, thereby increasing the risk of air environmental pollution to the first conductive bump 111 and affecting the reliability of the package structure; if the distance of the barrier structure 102 and the nearest first conductive bump 111 in the first direction are too large, then due to the limitation of the substrate space, it is not conducive to arranging the barrier structure 102 on the substrate or only one barrier structure 102 can be arranged in the space. For this reason, in the present embodiment, the direction close to the edge of the substrate 100 is defined as the first direction, and the distance of the barrier structure 102 and the nearest first conductive bump 111 in the first direction are between 100 micrometers and 300 micrometers.

It should be noted that the underfill layer 110 serves to adhere the optical device 101 on the substrate 100, preventing the risk of loosening or separation between the optical device 101 and the substrate 100, thereby improving the reliability of the package structure, meanwhile, the underfill layer 110 also serves for protection between the optical device 101 and the substrate 100, preventing the package structure from being damaged by dust or moisture in the external environment.

In the present embodiment, the underfill layer 110 covers the sidewalls of the first conductive bump 111.

In some implementations, the underfill layer 110 covers the sidewalls of the first conductive bump 111, reducing the exposure of the first conductive bump 111 to the air environment, reducing the risk of dust or moisture contamination on the first conductive bump 111, and improving the reliability of the package structure.

As an example, the material of the underfill layer 110 includes epoxy resin.

Correspondingly, FIGS. 8 to 9 illustrate structural schematic diagrams corresponding to the second embodiment of the package structure of the present disclosure.

The similarities between the package structure of the present disclosure and the first embodiment will not be repeated herein, and the difference between the package structure of the present disclosure and the first embodiment lies in:

Referring to FIGS. 8 to 9, the barrier structure 202 is also located on the surface of the optical device 201 facing the edge area.

It should be noted that the barrier structure 202 is also located on the surface of the optical device 201 facing the edge area, during the process of arranging the underfill layer between the optical device 201 and the substrate of the electrical connection area, the barrier structure 202 can also block the probability of the underfill layer overflowing the periphery of the substrate through the surface of the optical device 201 facing the edge region, thereby further improving the reliability of the package structure and product yield.

As shown in FIG. 8, in the present embodiment, along the direction close to the edge of the substrate, the barrier structures 202 located on the edge area and the barrier structures 202 located on the optical device 201 are arranged in a staggered manner.

In some implementations, the barrier structures 202 on the edge area and the barrier structures 202 on the optical device 201 are arranged in a staggered manner, such that the barrier structures 202 on the edge area and the barrier structures 202 on the optical device 201 form a tooth-like structure, during the process of arranging the underfill layer between the optical device 201 and the substrate of the electrical connection area, even if the underfill layer overflows the first barrier structure 202, the tooth-like structure formed by the combination of the barrier structures 202 can still serve to block the underfill layer from overflowing the periphery of the substrate, thereby further improving the blocking effect of the barrier structure 202.

As shown in FIG. 9, in other embodiments, along the direction close to the edge of the substrate, the barrier structures 202 located on the edge area and the barrier structures 202 located on the optical device 201 are arranged in a crossed manner.

In some implementations, the barrier structures 202 on the edge area and the barrier structures 202 on the optical device 201 are arranged in a crossed manner, such that the barrier structures 202 on the edge area and the barrier structures 202 on the optical device 201 form a comb-like structure, the barrier structure 202 of the comb-like structure has overlapping areas in the longitudinal direction, and during the process of arranging the underfill layer between the optical device 201 and the substrate of the electrical connection area, the comb-like structure formed by a plurality of barrier structures 202 can further block the underfill layer from overflowing the periphery of the substrate, thereby further improving the blocking effect of the barrier structure 202.

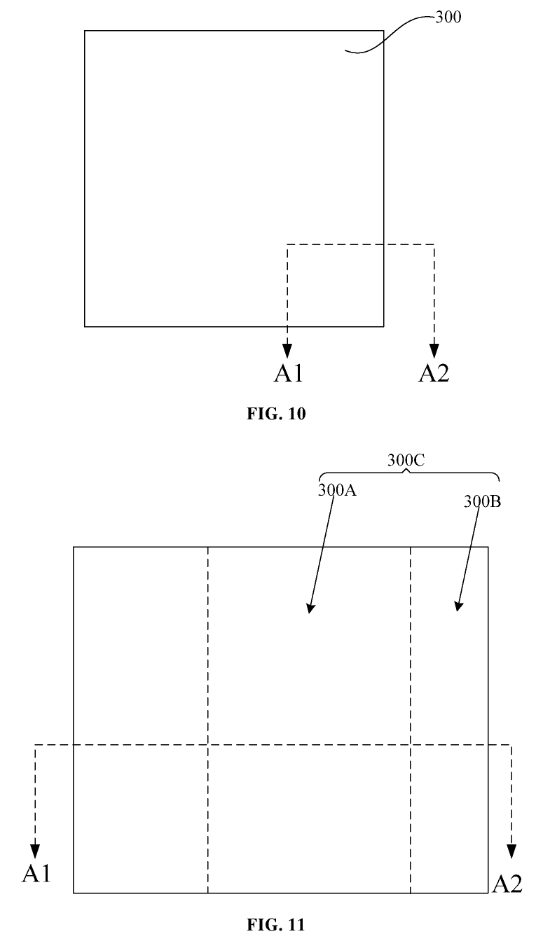

Correspondingly, the embodiment of the present disclosure also provides a method for forming a package structure. Wherein FIGS. 10 to 17 are structural schematic diagrams corresponding to each step of the first embodiment of the formation method of the package structure of the present disclosure

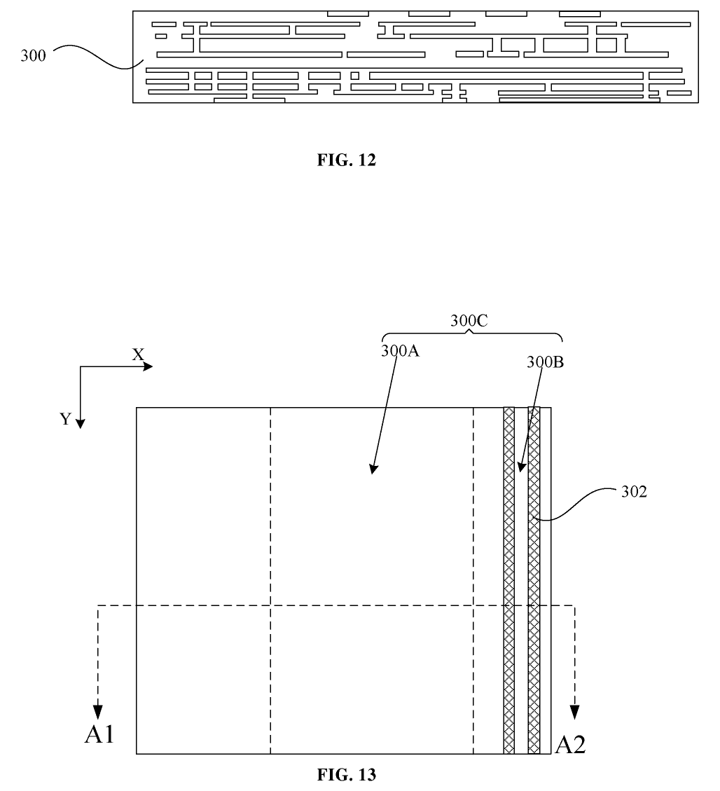

Referring to FIGS. 10 to 12, wherein FIG. 10 is a top view schematic diagram of the substrate, FIG. 11 is a top view schematic diagram of the optical module area, and FIG. 12 is a cross-sectional schematic diagram of FIG. 11 along the A1A2 direction, a substrate 300 is provided, the substrate 300 includes an optical module area 300C, and the optical module area 300C includes an electrical connection area 300A arranged along the direction close to an edge of the substrate 300 and an edge area 300B adjacent to it.

In some implementations, the substrate 300 provides a process platform for arranging the optical device to support the optical device, meanwhile, the substrate 300 has in it conductive lines, the conductive lines are used to supply power or transmit electrical signals for the optical device, thereby achieving the package and circuit integration of the optical device.

In the present embodiment, the substrate 300 may be one of silicon substrate, RDL substrate, resin substrate, Printed Circuit Board (PCB), ceramic substrate, glass substrate, or Flexible Printed Circuit (FPC). In one embodiment, the substrate 300 may be a single-layer board or a multi-layer board. In one embodiment, the substrate 300 may serve as an interposer board (or interposer).

In some implementations, the optical module area 300C is the area for subsequent arrangement of the optical devices, by arranging the optical devices on the substrate 300, the distance between the optical devices and other chips can be shortened, which improves the transmission speed of electrical signals, achieving lower signal latency and lower power consumption.

As an example, the optical module area 300C includes an electrical connection area 300A arranged along a direction close to an edge of the substrate 300 and an edge area 300B adjacent to it.

It should be noted that the electrical connection area 300A is the area where the optical device is electrically connected with the substrate 300, in some implementations, it is the area where the conductive bumps in the optical device are electrically connected with the substrate 300.

It should also be noted that the edge area 300B is the area where the barrier structure is arranged, by arranging the barrier structure at the edge area 300B, it can block the underfill layer from overflowing toward the direction close to the edge area 300B, the probability of the underfill layer overflowing the periphery of the substrate 300 is reduced, so that the reliability of the package structure and product yield are improved.

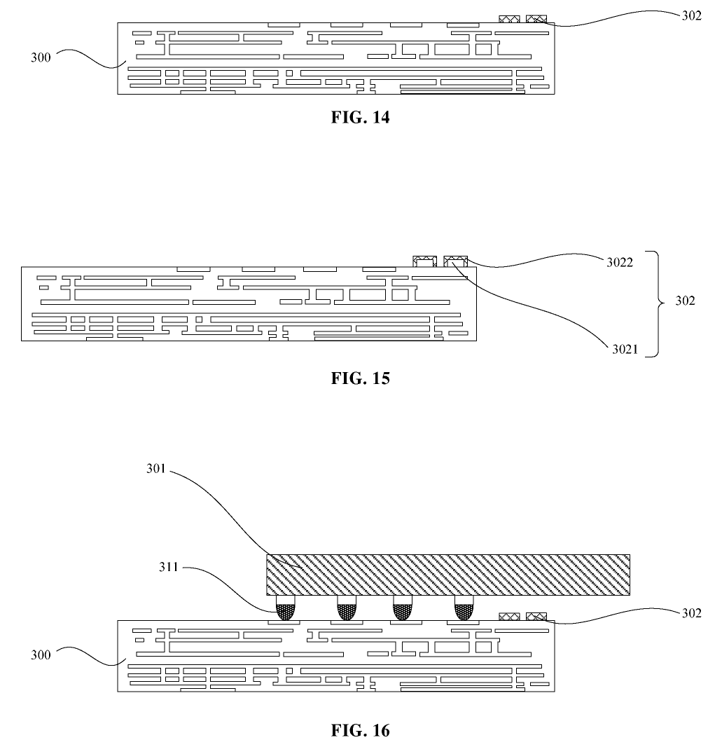

Referring to FIGS. 13 to 15, wherein FIG. 13 is a top view schematic diagram of the optical module area, and FIG. 14 is a cross-sectional schematic diagram of FIG. 13 along the A1A2 direction, a barrier structure 302 is formed at the top of the substrate 300 of the edge area 300B, and the surface of barrier structure 302 has a non-wetting material.

It should be noted that the barrier structure 302 is formed on the top of the substrate 300 of the edge area 300B, and the surface of the barrier structure 302 has a non-wetting material; since the surface of the barrier structure 302 has a non-wetting material, the non-wetting material has the function of blocking the overflow of liquid material, during the subsequent formation of the underfill layer, the barrier structure 302 can block the underfill layer from overflowing toward the direction close to the edge area 300B, the probability of the underfill layer overflowing the periphery of the substrate 300 is reduced, so that the reliability of the package structure and product yield are improved.

In the present embodiment, the barrier structure 302 includes a one-piece structural layer.

In some implementations, the one-piece structural layer refers to barrier structure 302 which is made of the same material.

In the present embodiment, the material of the one-piece structural layer includes a non-wetting material.

It should be noted that the barrier structure 302 is made of non-wetting material, the non-wetting material serves to block the overflow of liquid material, so that the barrier structure 302 can block the underfill layer from overflowing towards the edge area 300B.

In other embodiments, as shown in FIG. 15, the barrier structure 302 may further include a base material layer 3021 and a barrier layer 3022 covering the surface of the base material layer 3021.

The barrier layer 3022 is formed on the surface of the base material layer 3021, and the surface of the barrier layer 3022 has a non-wetting material, which enables the barrier layer 3022 to block the underfill layer from overflowing toward the direction of the edge area 300B, reducing the probability of the underfill layer overflowing the periphery of the substrate 300.

The base material layer 3021 serves to support the barrier layer 3022, ensuring that the entire barrier structure 302 has a certain strength and height.

In some implementations, the material of the barrier layer 3022 includes a non-wetting material.

The material of the barrier layer 3022 is made of non-wetting material, the non-wetting material serves to block the overflow of liquid materials, correspondingly, during the process of arranging the underfill layer between the optical device and the substrate 300 of the electrical connection area 300A, the barrier layer 3022 can block the underfill layer from overflowing toward the direction of the edge area 300B, reducing the probability of the underfill layer overflowing the periphery of the substrate 300.

In the present embodiment, the non-wetting material includes one or two of silicon oxide and silicon nitride.

Silicon oxide and silicon nitride have high density and are non-conductive, and thus will not affect circuits in the optical devices, meanwhile, silicon oxide and silicon nitride can block the underfill layer from overflowing toward the direction of the edge area 300B, reducing the probability of the underfill layer overflowing the periphery of the substrate 300.

As an example, the process for forming the barrier structure 302 at the top of the substrate 300 of the edge area 300B includes a spraying process, a printing process, or a sputtering process.

In the present embodiment, the direction close to the edge of the substrate 300 is defined as the first direction (as shown in the X-direction in FIG. 13), the barrier structure 302 extends along a second direction (as shown in the Y-direction in FIG. 13) and are arranged in parallel and spaced apart along the first direction, the first direction and the second direction being perpendicular to each other.

It should be noted that the barrier structures 302 are arranged in parallel and spaced apart along the first direction, during the subsequent process of arranging the underfill layer between the optical device and the substrate 300 of the electrical connection area 300A, even if the underfill layer overflows the first barrier structure 302, subsequent barrier structures 302 in the first direction can still serve to block the overflow of the underfill layer, reducing the probability of the underfill layer 110 overflowing the periphery of the substrate 300.

It should also be noted that the barrier structure 302 extends along the second direction, that is to say, the boundary of the electrical connection area 300A close to the edge of the substrate 300 is enclosed by the barrier structure 302, so that the overflow of the underfill layer of the entire electrical connection area 300A is blocked by the barrier structure 302, further reducing the probability of the underfill layer overflowing the periphery of the substrate 300.

In some implementations, the number of barrier structures 302 should not be too much. If the number of barrier structures 302 is too much, it tends to cause the area of edge area 300B occupied by the barrier structures 302 to be too large, in the case where the area of the optical module area 300C is fixed, the area of the electrical connection area 300A is reduced, thereby decreasing the joint area between optical device and substrate 300, increasing the risk of separation between the optical device and the substrate 300, meanwhile, it also affects the electrical connection effectiveness between the optical device and the substrate 300. For this reason, in the present embodiment, the number of barrier structures 102 is between 1 and 4.

It should be noted that the direction close to the edge of the substrate 300 is defined as the first direction, the distance of the barrier structure 302 in the first direction should be neither too small nor too large. If the distance of the barrier structure 302 in the first direction is too small, it increases the process difficulty for forming the barrier structure 302 during the formation of the barrier structure 302, meanwhile, it also affects the effectiveness of the barrier structure 302 in blocking the overflow of liquid materials, increasing the probability of the underfill layer overflowing the periphery of the substrate 300; if the distance of the barrier structure 302 in the first direction is too large, it tends to cause the area of the edge area 300B occupied by the barrier structure 302 to be too large, in the case where the area of the optical module area 300C is fixed, the area of the electrical connection area 300A is reduced, thereby decreasing the joint area between optical device and substrate 300, increasing the risk of separation between the optical device and the substrate 300. For this reason, in the present embodiment, the direction close to the edge of the substrate 300 is defined as the first direction, and the distance of the barrier structure 302 in the first direction is between 10 micrometers and 20 micrometers.

In some implementations, in the normal direction of the substrate 300, there is a first spacing between the optical device and the substrate 300, and the percentage of the height of the barrier structure 302 relative to the first spacing should be neither too large nor too small. If the percentage of the height of the barrier structure 302 relative to the first spacing is too small, then it affects the effectiveness of the barrier structure 302 in blocking the overflow of liquid materials, increasing the probability of the underfill layer overflowing the periphery of the substrate 300; if the percentage of the height of the barrier structure 302 relative to the first spacing is too large, then the manufacturing difficulty and manufacturing cost of the barrier structure 302 is higher. For this reason, in the present embodiment, in the normal direction of the substrate 300, there is a first spacing between the optical device and the substrate 300, and the height of the barrier structure 302 is between 5% and 25% of the first spacing.

It should be noted that the direction close to the edge of the substrate 300 is defined as the first direction, the distance of the barrier structure 302 and the nearest first conductive bump 311 in the first direction should be neither too small nor too large. If the distance of the barrier structure 302 and the nearest first conductive bump 311 in the first direction are too small, then it increases the difficulty of arranging the underfill layer between the barrier structure 302 and the nearest first conductive bump 311, which prevents the underfill layer from fully covering the sidewalls of the first conductive bump 311, increasing the risk of the sidewalls of the first conductive bump 311 of the nearest barrier structure 302 being exposed, thereby increasing the risk of air environmental pollution to the first conductive bump 311 and affecting the reliability of the package structure; if the distance of the barrier structure 302 and the nearest first conductive bump 311 in the first direction are too large, then due to the limitation of the substrate space, it is not conducive to arranging the barrier structure 302 on the substrate or only one barrier structure 302 can be arranged in the space. For this reason, in the present embodiment, the direction close to the edge of the substrate 300 is defined as the first direction, and the distance of the barrier structure 302 and the nearest first conductive bump 311 in the first direction are between 100 micrometers and 300 micrometers.

Referring to FIG. 16, an optical device 301 is arranged at the top of the substrate 300 of the optical module area 300C, and the electrical connection area 300A of the substrate 300 is electrically connected with the optical device 301.

In some implementations, the optical device 301 is used to receive optical signals, by arranging the optical device 301 in the optical module area 300C of the substrate 300, a shorter optical path can be achieved, thereby improving the efficiency of optical communication.

As an example, in order to facilitate the reception of optical signals by the optical device 301, the optical device 301 partially protrudes from the periphery of the substrate 300.

As an example, the optical device 301 includes one or two of a photodetector chip and an optical transceiver.

In the present embodiment, the step of arranging the optical device 301 at the top of the substrate 300 of the optical module area 300C includes: providing the optical device 301, a first conductive bump 311 is formed on the surface of the optical device 301 facing the substrate 300, and the top surface of the first conductive bump 311 is electrically connected with the optical device 301; and soldering the first conductive bump 311 to the electrical connection area 300A of the substrate 300 through a high-temperature reflow process, and the bottom surface of the first conductive bump 311 is electrically connected with the electrical connection area 300A of the substrate 300.

It should be noted that the first conductive bump 311 serves to arrange the optical device 301 on the substrate 300, which reduces the risk of the optical device 301 and the substrate 300 separating from each other, meanwhile, the first conductive bump 311 also serves to achieve electrical connection between the optical device 301 and the substrate 300.

It should also be noted that by forming the first conductive bump 311 on the surface of the optical device 301 facing the substrate 300 through an electroplating process, it enables the first conductive bump 311 to be formed at a designated position of the electrical connection area 300A of the substrate 300, meanwhile, the first conductive bump 311 formed through an electroplating process has the characteristics of high connection reliability, and etc., which can reduce the risk of separation between the first conductive bump 311 and the substrate 300.

As an example, the material of the first conductive bump 311 includes one or more of gold, lead-tin, silver-tin, gold-tin, and copper-tin.

In some implementations, using the high-temperature reflow process enables local heating for merely the first conductive bump 311 and substrate 300 to complete the soldering, reducing the probability of thermal shock to other components of the package structure; meanwhile, the high-temperature reflow process allows excess flux within the first conductive bump 311 to fully evaporate, reducing the residue after soldering and thereby improving the soldering quality.

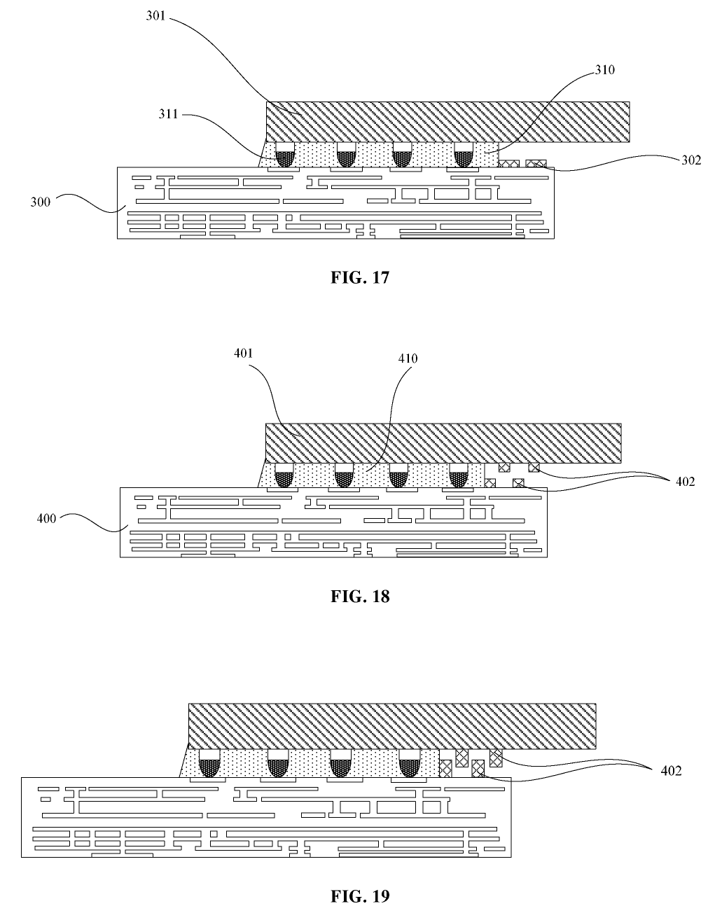

Referring to FIG. 17, after forming the optical device 301 and the barrier structure 302, an underfill layer 310 is formed between the optical device 301 and the substrate 300 of the electrical connection area 300A, and the underfill layer 310 contacts both the substrate 300 and the optical device 301.

It should be noted that the underfill layer 310 serves to adhere the optical device 301 on the substrate 300, preventing the risk of loosening or separation between the optical device 301 and the substrate 300, thereby improving the reliability of the package structure, meanwhile, the underfill layer 310 also serves for protection between the optical device 301 and the substrate 300, preventing the package structure from being damaged by dust or moisture in the external environment.

In the present embodiment, in the step of forming the underfill layer 310, the underfill layer 310 covers the sidewalls of the first conductive bump 311.

In some implementations, the underfill layer 310 covers the sidewalls of the first conductive bump 311, reducing the exposure of the first conductive bump 311 to the air environment, reducing the risk of dust or moisture contamination on the first conductive bump 311, and improving the reliability of the package structure.

As an example, the material of the underfill layer 310 includes epoxy resin.

Correspondingly, FIGS. 18 to 19 illustrate structural schematic diagrams corresponding to each step of the second embodiment of the formation method of the package structure of the present disclosure.

The similarities between the formation method of the package structure of the present disclosure and the first embodiment will not be repeated herein, and the difference between the formation method of the package structure of the present disclosure and the first embodiment lies in:

Referring to FIGS. 18 to 19, in the step of forming the barrier structure 402, it further includes: forming the barrier structure 402 on the surface of the optical device 401 facing the edge area.

It should be noted that by forming the barrier structure 402 on the surface of the optical device 401 facing the edge area, during the process of forming an underfill layer 410 between the optical device 401 and the substrate 400 of the electrical connection area, the barrier structure 402 can also block the probability of the underfill layer 410 overflowing the periphery of the substrate 400 through the surface of the optical device 401 facing the edge area, thereby further improving the reliability of the package structure and product yield.

As shown in FIG. 18, in the present embodiment, along the direction close to the edge of the substrate, during the step of forming the barrier structure 402, the barrier structures 402 located on the edge area and the barrier structures 402 located on the optical device 201 are arranged in a staggered manner.

In some implementations, the barrier structures 402 on the edge area and the barrier structures 402 on the optical device 401 are arranged in a staggered manner, such that the barrier structures 402 on the edge area and the barrier structures 402 on the optical device 401 form a tooth-like structure, during the process of forming the underfill layer 410 between the optical device 401 and the substrate 400 of the electrical connection area, even if the underfill layer 410 overflows the first barrier structure 402, the tooth-like structure formed by the combination of the barrier structures 402 can still serve to block the underfill layer 410 from overflowing the periphery of the substrate 400, thereby further improving the blocking effect of the barrier structure 402.

As shown in FIG. 19, in other embodiments, along the direction close to the edge of the substrate 400, during the step of forming the barrier structure 402, the barrier structures 402 located on the edge area and the barrier structures 402 located on the optical device 401 are arranged in a crossed manner.

In some implementations, the barrier structures 402 on the edge area and the barrier structures 402 on the optical device 401 are arranged in a crossed manner, such that the barrier structures 402 on the edge area and the barrier structures 402 on the optical device 401 form a comb-like structure, the barrier structure 402 of the comb-like structure has overlapping areas in the longitudinal direction, and during the process of forming the underfill layer 410 between the optical device 401 and the substrate 400 of the electrical connection area, the comb-like structure formed by a plurality of barrier structures 402 can further block the underfill layer 410 from overflowing the periphery of the substrate 400, thereby further improving the blocking effect of the barrier structure 402.

Although the present disclosure is disclosed as above, but the present disclosure is not limited to this. Any skilled in the art may also make various changes and modifications without departing from the spirit and scope of the present disclosure, therefore the scope of protection of the present disclosure should be based on the scope defined by the claims.

What is claimed is:

1. A package structure, comprising:
a substrate, wherein the substrate comprises an optical module area, the optical module area comprises an electrical connection area and an edge area adjacent thereto arranged in a direction toward an edge of the substrate;
an optical device arranged on a top of the substrate in the optical module area, wherein the electrical connection area of the substrate is electrically connected to the optical device;
a barrier structure located at the top of the substrate in the edge area, wherein a surface of the barrier structure is provided with a non-wetting material; and
an underfill layer located between the optical device and the substrate in the electrical connection area, wherein the underfill layer is in contact with the substrate and the optical device.

2. The package structure according to claim 1, wherein the barrier structure comprises a one-piece structural layer; or
the barrier structure comprises a base material layer and a barrier layer covering a surface of the base material layer.

3. The package structure according to claim 2, wherein a material of the one-piece structural layer comprises a non-wetting material; or
a material of the barrier layer comprises a non-wetting material.

4. The package structure according to claim 1, wherein the non-wetting material comprises at least one of silicon oxide or silicon nitride.

5. The package structure according to claim 1, wherein the direction toward the edge of the substrate is defined as a first direction, the barrier structure extends along a second direction and is arranged in parallel and spaced apart along the first direction, and the first direction and the second direction are perpendicular to each other.

6. The package structure according to claim 1, wherein a number of the barrier structures is between 1 and 4.

7. The package structure according to claim 1, wherein the direction toward the edge of the substrate is defined as a first direction, and a distance of the barrier structure in the first direction is 10 micrometers to 20 micrometers.

8. The package structure according to claim 1, wherein in a normal direction of the substrate, the optical device and the substrate are spaced apart by a first distance, and a height of the barrier structure is between 5% and 25% of the first distance.

9. The package structure according to claim 1, further comprising:
a first conductive bump located on a surface of the optical device facing the substrate, wherein:
a top surface of the first conductive bump is electrically connected to the optical device, and a bottom surface of the first conductive bump is electrically connected with the electrical connection area of the substrate;
the underfill layer covers sidewalls of the first conductive bump; and
the direction toward the edge of the substrate is defined as a first direction, and a distance in the first direction between the barrier structure and a nearest one of the first conductive bump is between 100 micrometers and 300 micrometers.

10. The package structure according to claim 1, wherein the optical device spans across the edge area of the substrate and protrudes beyond the substrate.

11. The package structure according to claim 1, wherein the barrier structure is further located on a surface of the optical device facing the edge area.

12. The package structure according to claim 11, wherein along the direction toward the edge of the substrate, the barrier structure on the edge area and the barrier structure on the optical device are arranged in a staggered manner; or
along the direction toward the edge of the substrate, the barrier structure on the edge area and the barrier structure on the optical device are arranged in an intersecting manner.

13. The package structure according to claim 1, wherein a material of the underfill layer comprises epoxy resin.

14. A method for forming a package structure, comprising:
providing a substrate, wherein the substrate comprises an optical module area, the optical module area comprises an electrical connection area and an edge area adjacent thereto arranged in a direction toward an edge of the substrate;
forming a barrier structure on a top of the substrate in the edge area, wherein a surface of the barrier structure is provided with a non-wetting material;
after forming the barrier structure, arranging an optical device on the top of the substrate in the optical module area, wherein the electrical connection area of the substrate is electrically connected to the optical device; and
after forming the optical device and the barrier structure, forming an underfill layer between the optical device and the substrate in the electrical connection area, wherein the underfill layer is in contact with the substrate and the optical device.

15. The method for forming a package structure according to claim 14, wherein the barrier structure comprises a one-piece structural layer; or
the barrier structure comprises a base material layer and a barrier layer covering a surface of the base material layer.

16. The method for forming a package structure according to claim 15, wherein a material of the one-piece structural layer comprises a non-wetting material; or
a material of the barrier layer comprises a non-wetting material.

17. The method for forming a package structure according to claim 14, wherein a process for forming the barrier structure on the top of the substrate in the edge area comprises a spray coating process, a printing process, or a sputtering process.

18. The method for forming a package structure according to claim 14, wherein the arranging the optical device on the top of the substrate in the optical module area comprises:
providing the optical device, wherein a first conductive bump is formed on a surface of the optical device facing the substrate, and a top surface of the first conductive bump is electrically connected to the optical device; and
bonding the first conductive bump to the electrical connection area of the substrate via a high-temperature reflow process, wherein a bottom surface of the first conductive bump is electrically connected to the electrical connection area of the substrate,
wherein, in the forming the underfill layer, the underfill layer covers sidewalls of the first conductive bump.

19. The method for forming a package structure according to claim 14, wherein in the forming the barrier structure further comprises:
forming the barrier structure on a surface of the optical device facing the edge area,
wherein, along the direction toward the edge of the substrate, the barrier structure on the edge area and the barrier structure on the optical device are arranged in a staggered manner in the forming the barrier structure; or
along the direction toward the edge of the substrate, the barrier structure on the edge area and the barrier structure on the optical device are arranged in an intersecting manner in the forming the barrier structure.

20. The method for forming a package structure according to claim 14, wherein the direction toward the edge of the substrate is defined as a first direction, the barrier structure extends along a second direction and is arranged in parallel and spaced apart along the first direction, and the first direction and the second direction are perpendicular to each other.
